(19) United States
(12) Patent Application Publication
(10) Pub. No.: US 2017/0168977 A1
(43) Pub. Date: Jun. 15, 2017

(54) PCB APPARATUS, MODULE AND METHOD FOR FUNCTION EXTENSION

(71) Applicants: Le Holdings (Beijing) Co., Ltd., Beijing (CN); LE SHI ZHI XIN ELECTRONIC TECHNOLOGY (TIANJIN) LIMITED, Tianjin (CN)

(72) Inventor: Xiaoming HOU, Tianjin (CN)

(21) Appl. No.: 15/250,521

(22) Filed: Aug. 29, 2016

Related U.S. Application Data
(63) Continuation of application No. PCT/CN2016/088580, filed on Jul. 5, 2016.

(30) Foreign Application Priority Data
Dec. 9, 2015 (CN) 201510919338.1

(51) Int. Cl. G06F 13/42; G06F 13/40; H05K 1/18

(52) U.S. Cl. CPC G06F 13/4282; H05K 1/18; G06F 13/4095; H05K 2201/09063

(57) ABSTRACT

A PCB apparatus, a module board, and a method for function extension is disclosed. The PCB apparatus includes a substrate for PCB design, and further includes: at least one module board, integrated with a performance enhancing module; and a connector, the module board being connected to the substrate through the connector, such that the module board and the substrate perform signal transmission.

### CROSS REFERENCE TO RELATED APPLICATIONS

This application is a continuation of International Application No. PCT/CN2016/088580 filed on Jul. 5, 2016, which is based upon and claims priority to Chinese Patent Application No. 2015109193381, filed before Chinese Patent Office on Dec. 9, 2015 and entitled “PCB APPARATUS, MODULE BOARD, AND METHOD FOR FUNCTION EXTENSION”, the entire contents of which are incorporated herein by reference.

### TECHNICAL FIELD

The present disclosure relates to the technical field of PCB design, and more particularly, to a PCB apparatus, a module board, and a method for function extension.

### BACKGROUND

A printed circuit board (PCB) is an important electronic part, a support of electronic components and a carrier of electrical connections of the electronic components. During the development of products, the development and design of the products are generally implemented through PCB design.

During the implementation of the present disclosure, the inventor finds at least the following problem in the related art. The upgrading of existing design of smart electrical devices is fast. Even on the same platform, mainboards of different solutions are still made to grade the products into high, medium and low classes, which results in that multiple PCB designs need to be maintained in the development and design. The upgrading or modification on a product can only be carried out through re-design by changing the PCB.

Therefore, it is a technical problem to be solved urgently in the related art on how to extend functions in PCB design.

### SUMMARY

The present disclosure provides a PCB apparatus, a module board, and a method for function extension, in which functions are extended in PCB design, thereby reducing the workload of design and development as well as the risk of purchasing excess materials so the design and development are more flexible.

In a first aspect, embodiments of the present disclosure provide a PCB apparatus for function extension, which includes a substrate for PCB design;

at least one module board, integrated with a performance enhancing module; and

a connector, the module board being connected to the substrate through the connector, such that the module board and the substrate perform signal transmission.

In a second aspect, embodiments of the present disclosure further provide a module board for function extension, wherein the module board is integrated with a performance enhancing module, and the module board is connected to a substrate for PCB design through a connector, such that the module board and the substrate perform signal transmission through the connector.

In a third aspect, embodiments of the present disclosure further provide a method for function extension of a PCB apparatus, which includes:

connecting at least one module board integrated with a performance enhancing module, to a substrate through a connector, such that the module board and the substrate perform signal transmission through the connector.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic structural diagram illustrating a PCB apparatus for function extension according to the present disclosure;

FIG. 2 is a schematic structural diagram illustrating a module board for function extension according to the present disclosure;

FIG. 3 is a flowchart illustrating a method for function extension of a PCB apparatus according to the present disclosure;

FIG. 4 is a schematic structural diagram illustrating a specific disclosure of a PCB apparatus for function extension according to the present disclosure; and

FIG. 5 is a diagram illustrating the principle of signal definition in a specific disclosure of a PCB apparatus for function extension according to the present disclosure.

### DETAILED DESCRIPTION

In the present disclosure, a module board is integrated with a performance enhancing module, and the module board is connected to a substrate for PCB design through a connector, such that the module board and the substrate perform signal transmission through the connector. Therefore, when a product needs to be upgraded or modified in the present disclosure, the module board integrated with the performance enhancing module can be used for function extension, and the PCB design of the substrate does not need to be changed, thereby reducing the workload of design and development as well as the risk of purchasing excess materials so the design and development are more flexible.

Definitely, the implementation of any technical solution of the present disclosure does not need to achieve all the above advantages.

To make a person skilled in the art better understand the technical solutions of the present disclosure, the technical solutions in the embodiments of the present disclosure are described clearly and completely with reference to the accompanying drawings in the embodiments of the present disclosure. Apparently, the described embodiments are merely some of rather than all of the embodiments of the present disclosure. Based on the embodiments of the present disclosure, all other embodiments derived by a person of ordinary skill in the art shall fall within the protection scope of the present disclosure.

The specific implementation of the present disclosure is described in detail below with reference to the accompanying drawings of the present disclosure.

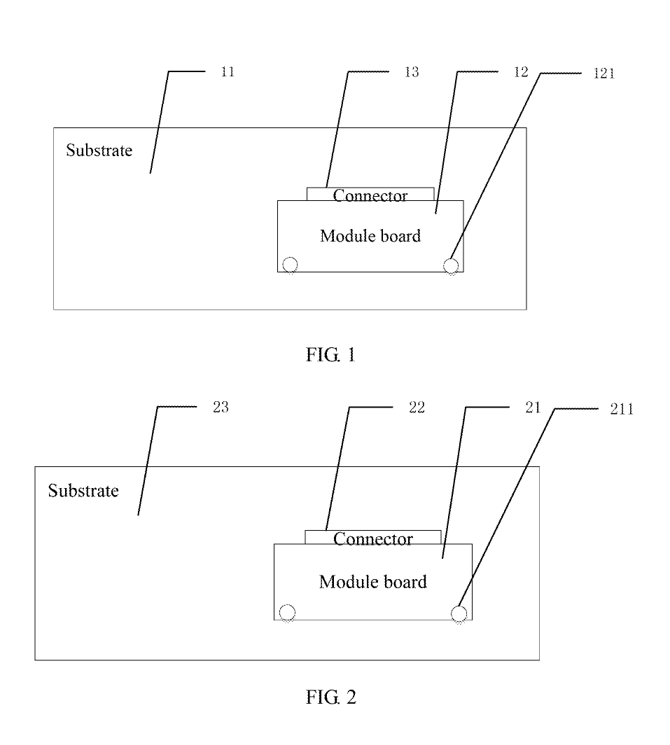

Referring to FIG. 1, a specific embodiment of the present disclosure provides a PCB apparatus for function extension, which includes a substrate 11 for PCB design, and further includes:

at least one module board 12, integrated with a performance enhancing module; and

a connector 13, the module board 12 being connected to the substrate 11 through the connector 13, such that the module board 12 and the substrate 11 perform signal transmission.

Therefore, when a product needs to be upgraded or modified in the present disclosure, the module board integrated with the performance enhancing module can be used for function extension, and the PCB design of the substrate does not need to be changed, thereby reducing the workload of design and development as well as the risk of purchasing excess materials so the design and development are more flexible.

A PCIE interface is a high-speed serial point-to-point two-channel high-bandwidth transmission interface. It allocates an exclusive channel bandwidth to a device connected to the PCIE interface, and does not share a bus bandwidth, and mainly supports functions such as active power management, error report, end-to-end reliable transmission, hot-plugging and quality of service (QoS).

Because the PCIE interface has the above advantages, the connector 13 in the present disclosure includes a PCIE interface, and the module board 12 and the substrate 11 are connected through the PCIE interface.

The PCIE interface is generally used for transmitting a PCIE signal, and data signals and control signals transmitted between the PCIE interfaces are defined through a private protocol in the present disclosure, thereby realizing signal transmission between the module board 12 and the substrate 11.

The private protocol is defined by a person of ordinary skill in the art according to the performance enhancing module integrated on the module board 12.

In this way, when a product needs to be upgraded or modified, the substrate does not need to be changed, and only the module'board integrated with a different performance enhancing module needs to be replaced to realize high, medium and low-level configuration of the product, thereby reducing the workload of design and development as well as the risk of purchasing excess materials so the design and development are more flexible and convenient

In a specific implementation of the present disclosure, the module board 12 further includes screw positioning holes 121 for fixing the module board 12 to the substrate 11.

To ensure that the module board 12 is securely fixed on the substrate 11, two screw positioning holes 121 are provided, and the two screw positioning holes 121 are located in two opposite corners on one side of the module board 12 facing the PCIE interface.

Referring to FIG. 2. another specific embodiment of the present disclosure provides a module board 21 for function extension, wherein the module board 21 is integrated with a performance enhancing module, and the module board 21 is connected to a substrate 23 for PCB design through a connector 22, such that the module board 21 and the substrate 23 perform signal transmission through the connector 22.

Therefore, when a product needs to be upgraded or modified in the present disclosure, the module board integrated with the performance enhancing module can be used for function extension, and the PCB design of the substrate does not need to be changed, thereby reducing the workload of design and development as well as the risk of purchasing excess materials so the design and development are more flexible.

A PCIE interface is a high-speed serial point-to-point two-channel high-bandwidth transmission interface, allocates an exclusive channel bandwidth to a device connected to the PCIE interface, does not share a bus bandwidth, and mainly supports functions such as active power management, error report, end-to-end reliable transmission, hot-plugging and QoS.

Because the PCIE interface has the above advantages, the connector 22 in the present disclosure includes a PCIE interface, and the module board 21 and the substrate 23 are connected through the PCIE interface.

The PCIE interface is generally used for transmitting a PCIE signal, and data signals and control signals transmitted between the module board 21 and the substrate 23 are defined through a private protocol in the present disclosure, thereby realizing signal transmission between the module board 21 and the substrate 23.

The private protocol is defined by a person of ordinary skill in the art according to the performance enhancing module integrated on the module board 21.

In this way, when a product needs to be upgraded or modified, the substrate does not need to be changed, and only the module board integrated with a different performance enhancing module needs to be replaced to realize high, medium and low-level configuration of the product, thereby reducing the workload of design and development as well as the risk of purchasing excess materials so the design and development are more flexible and convenient.

In a specific implementation of the present disclosure, the module board 21 further includes screw positioning holes 211 for fixing the module board 21 to the substrate 23.

To ensure that the module board 21 is securely fixed on the substrate 23, two screw positioning, holes 211 are provided, and the two screw positioning holes 211 are located in two opposite corners on one side of the module board 21 facing the PCIE interface 221.

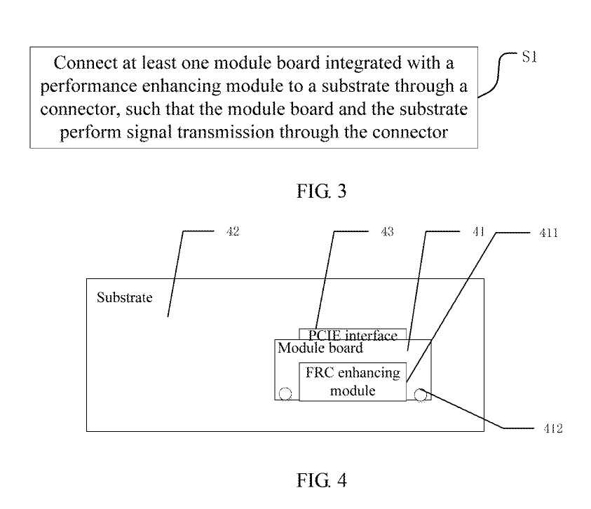

Referring to FIG. 3, another specific embodiment of the present disclosure provides a method for function extension of a PCB apparatus, which includes:

S1: At least one module board integrated with a performance enhancing module is connected to a substrate through a connector, such that the module board and the substrate perform signal transmission through the connector.

Therefore, when a product needs to be upgraded or modified in the present disclosure, the module board integrated with the performance enhancing module can be used for function extension, and the PCB design of the substrate does not need to be changed, thereby reducing the workload of design and development as well as the risk of purchasing excess materials so the design and development are more flexible.

A PCIE interface is a high-speed serial point-to-point two-channel high-bandwidth transmission interface, allocates an exclusive channel bandwidth to a device connected to the PCIE interface, does not share a bus bandwidth, and mainly supports functions such as active power management, error report, end-to-end reliable transmission, hot-plugging and QoS.

Because the PCIE interface has the above advantages, the module board and the substrate are connected through the PCIE interface in the present disclosure.

The PCIE interface is generally used for transmitting a PCIE signal, and data signals and control signals transmitted between the module board and the substrate are defined through a private protocol in the present disclosure, thereby realizing signal transmission between the module board and the substrate.

The private protocol is defined by a person of ordinary skill in the art according to the performance enhancing module integrated on the module board.

In this way, when a product needs to be upgraded or modified, the substrate does not need to be changed, and only the module board integrated with a different performance enhancing module needs to be replaced to realize high, medium and low-level configuration of the product, thereby reducing the workload of design and development as well as the risk of purchasing excess materials so the design and development are more flexible and convenient.

The implementation of the present disclosure is illustrated below through a specific disclosure scenario.

In most moving pictures, problems such as picture freezing or streaking are caused due to loss of a display frame rate. An FRC enhancing module (frame rate compensation chip) is generally added to enhance the display effect, such that the picture display is smoother and the product performance is improved.

When a smart television product needs to be upgraded in the above product performance, referring to FIG. 4, a module board 41 is integrated with an FRC enhancing module 411 (frame rate compensation chip), and the FRC enhancing module 411 is configured to enhance video display.

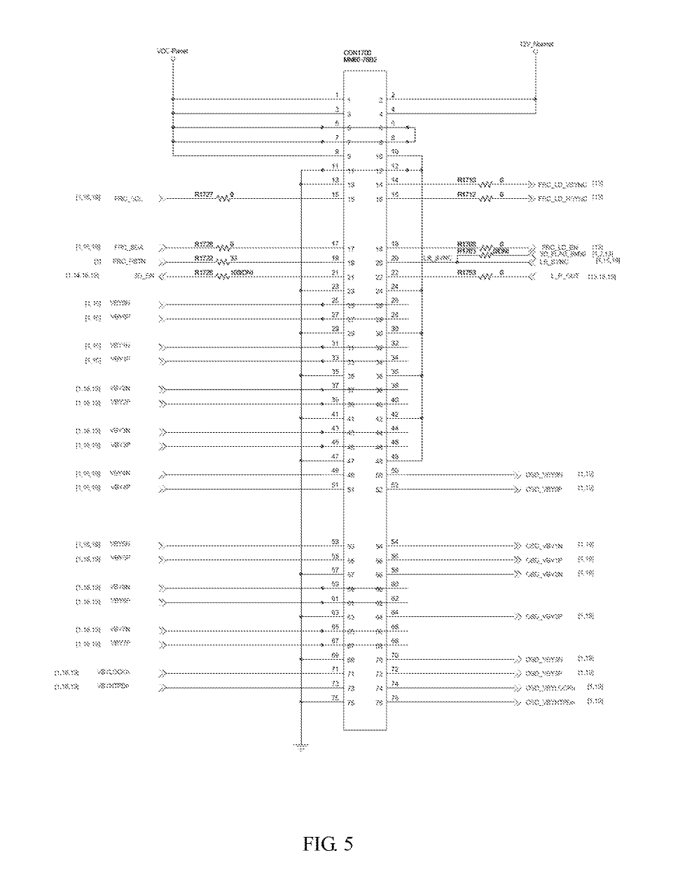

The module board 41 is connected to an original substrate 42 through a PCIE interface 43, and a private protocol is defined for the PCIE interface 43, as illustrated in FIG. 5. Therefore, the transmission of LVDS and VB1 video signals and control signals between the module board 41 and the original substrate 42 is realized.

The module board 41 is securely fixed on the substrate 42 through the PCIE interface 43 and the two screw positioning holes 412. An output interface of the FRC enhancing module 411 is a standard 51pin VB1 interface, and is set to be connected to an external display screen.

In this way, when the display effect of a smart television product needs to be enhanced to make the picture display smoother and improve the product performance, the substrate does not need to be changed, and only the module board integrated with the FRC enhancing module needs to be replaced to achieve product upgrading. Therefore, PCB design and development of the substrate do not need to be started over, so the design and development are more flexible and convenient.

Although the embodiments of the present disclosure are described above, once knowing the basic creative concept, a person skilled in the art can make other modifications and variations to these embodiments. Therefore, the appended claims are intended to be construed as covering the embodiments and all the modifications and variations falling within the scope of the present disclosure. Obviously, a person skilled in the art can make various modifications and variations to the present disclosure without departing from the spirit and scope of the present disclosure. In this way, the present disclosure is intended to cover the modifications and variations if they fall within the scope of the appended claims of the present disclosure and equivalent technologies thereof.

What is claimed is:

1. A PCB apparatus for function extension, comprising:
a substrate for PCB design;
at least one module board, integrated with a performance enhancing module; and
a connector, the module board being connected to the substrate through the connector, such that the module board and the substrate perform signal transmission.

2. The apparatus according to claim 1, wherein the connector comprises a PCIE interface, and the module board and the substrate perform signal transmission through the PCIE interface by using a private protocol.

3. The apparatus according to claim 2, wherein data signals and control signals are transmitted over the PCIE interface by using the private protocol.

4. The apparatus according to claim 1, wherein the module board is further fixed to screw positioning holes on the substrate.

5. The apparatus according to claim 4, wherein two screw positioning holes are provided, and the two screw positioning holes are located in two opposite corners on one side of the module board facing the PCIE interface.

6. A module board for function extension, wherein the module board is integrated with a performance enhancing module, and the module board is connected to a substrate for PCB design through a connector, such that the module board and the substrate perform signal transmission through the connector.

7. The module board according to claim 6, wherein the connector comprises a PCIE interface, and the module board and the substrate perform signal transmission through the POE interface by using a private protocol.

8. The module board according to claim 7, wherein data signals and control signals are transmitted over the PCIE interface by using the private protocol.

9. The module board according to claim 6, wherein the module board is further fixed to screw positioning holes on the substrate.

10. The module board according to claim 9, wherein two screw positioning holes are provided, and the two screw positioning holes are located in two opposite corners on one side of the module board facing the PCIE interface.

11. A method for function extension of a PCB apparatus. applied in an integrated circuit, and comprising:
connecting at least one module board integrated with a performance enhancing module to a substrate through a connector, such that the module board and the substrate perform signal transmission through the connector.

12. The method according to claim 11, wherein the module board and the substrate perform signal transmission through the PCIE interface by using a private protocol.

13. The method according to claim 12, wherein data signals and control signals are transmitted over the PCIE interface by using the private protocol.
